(19) United States
(12) Patent Application Publication
(10) Pub. No.: US 2026/0223757 A1
(43) Pub. Date: Jul. 30, 2026

(54) POWER SEMICONDUCTOR MODULE

(71) Applicants: Dynex Semiconductor Limited, Lincoln (GB); Zhuzhou CRRC Times Semiconductor Co. Ltd, Zhuzhou, Hunan (CN)

(72) Inventor: Yangang WANG, Lincoln (GB)

(21) Appl. No.: 19/141,636

(22) PCT Filed: Dec. 22, 2022
(86) PCT No.: PCT/EP2022/087502

§ 371 Date: Jun. 20, 2025

(51) Int. Cl. H10W 90/00; H10W 70/40; H10W 72/00; H10W 74/01; H10W 90/10

(52) U.S. Cl. CPC H10W 90/811; H10W 70/481; H10W 90/10; H10W 90/756; H10W 90/766; H10W 72/865; H10W 74/016

(57) ABSTRACT

A power semiconductor module comprises a power semiconductor die; a leadframe comprising a die pad and a power lead wherein the die pad has a first surface facing the power semiconductor die and a second surface opposite to the first surface, wherein a main surface of the power semiconductor die is directly attached to the first surface of the die pad, and a power electrode of the power semiconductor die is electrically connected to the power lead; a housing mounted on the leadframe and surrounding a periphery of the power semiconductor die, wherein the housing comprises an electrically insulating material; and an encapsulant surrounded by the housing and encapsulating the power semiconductor die and part of the leadframe. The second surface of the die pad is exposed to an exterior of the power semiconductor module.

### TECHNICAL FIELD

This disclosure relates to a power semiconductor module and a method of manufacturing the same. More particularly, but not exclusively, this disclosure relates to a compact and low-volume power semiconductor module which is free of any baseplate or substrate.

### BACKGROUND

Power semiconductor modules are the core components in power-train system of hybrid and electric vehicles (HEV/EV). With the global interests and efforts to popularize HEV/EV, automotive module has become one of the fast growing sectors of power semiconductor industry. However, the comprehensive requirements in power, frequency, efficiency, robustness, reliability, weight, volume, and cost of automotive module are stringent than industrial products due to extremely high standards of vehicle safety and harsh environment. The development of automotive power module is facing comprehensive challenges in designing of structure, material, and assembly technology.

The conventional power semiconductor modules typically use a sandwich structure with plain baseplate and/or direct bond copper (DBC) substrate interconnected by solder reflowing and wire bonding. The structure and technologies are generally difficult to meet HEV/EV requirements in thermal and mechanical performance, as well as in the reliability, lifetime, cost, volume, and weight.

It is an object of the present disclosure, among others, to provide an improved power semiconductor module that solves problems associated with conventional power semiconductor modules, whether identified herein or otherwise.

### SUMMARY

According to a first aspect of this disclosure, there is provided a power semiconductor module, comprising:
a power semiconductor die;
a leadframe comprising a die pad and a power lead, wherein the die pad has a first surface facing the power semiconductor die and a second surface opposite to the first surface, wherein a main surface of the power semiconductor die is directly attached to the first surface of the die pad, and a power electrode of the power semiconductor die is electrically connected to the power lead;
a housing mounted on the leadframe and surrounding a periphery of the power semiconductor die, wherein the housing comprises an electrically insulating material; and
an encapsulant surrounded by the housing and encapsulating the power semiconductor die and part of the leadframe, wherein the second surface of the die pad is exposed to an exterior of the power semiconductor module, and wherein at least a part of the power lead is also exposed to the exterior of the power semiconductor module.

Advantageously, by directly attaching the power semiconductor die to the first surface of the die pad, the leadframe acts as a die carrier to physically support the power semiconductor die. By further exposing the second surface of the die pad to an exterior of the power semiconductor module, the power semiconductor die is able to dissipate heat through the leadframe to the exterior. By having a power lead electrically connected to a power electrode of the power semiconductor die, the leadframe also electrically couples the power semiconductor die to an electronic environment of the module. Therefore, the use of the leadframe is beneficial for mechanical, thermal and electrical performance of the power semiconductor module.

By using the leadframe, there is no need to provide a further substrate (e.g., a DBC substrate) or a thick baseplate as commonly seen in conventional power semiconductor modules. Therefore, the power semiconductor module according to the first aspect can be free of any baseplate and substrate. This allows the power semiconductor module to be more compact and have a lower volume and hence a higher power density than conventional power semiconductor modules. Further, because the power semiconductor die is directly attached to the leadframe and the second surface of the leadframe is exposed to the exterior of the module, the junction-to-case thermal resistance of the power semiconductor module is at a very low level. Therefore, the junction temperature between the die and the leadframe would not increase significantly during operation of the power semiconductor module. This is beneficial for improving the power cycling capability and reliability of the power semiconductor module.

The use of the housing and the encapsulant improve the mechanical stability of the power semiconductor module. Further, the encapsulant is useful for protecting the power semiconductor die from humidity and corrosive gases.

With the expression “directly attached”, it is meant that no other structure is between the main surface of the power semiconductor die and the first surface of the die pad (except a small amount of bonding/interface material for joining the two surfaces). The main surface of the power semiconductor die may be directly attached to the first surface of the die pad by soldering or sintering.

Examples of the power semiconductor die include an insulated gate bipolar transistor (IGBT), a power diode, an injection enhanced gate transistor (IEGT), a power metal-oxide-semiconductor field effect transistor (MOSFET), a power bipolar junction transistor (BJT), an integrated gate-commutated thyristor (IGCT), and a gate turn-off thyristor (GTO), etc.

It would be understood that the power lead is for electrically coupling the module to an electronic environment. Different from a signal lead (also called a control lead) which carries a low-rating control signal, the power lead is typically connected to a high-rating power voltage/current in use.

The housing may also be referred to as a frame or a case, and is generally of a loop shape or a ring shape.

The power lead may extend from the die pad and be electrically connected to the die pad.

Therefore, the die pad and the power lead share substantially the same voltage potential in use, and can be regarded collectively as a large-area power terminal of the power semiconductor module. The large-area power terminal has a high current carrying capability, a high thermal dissipation rate and a low inductance, which are beneficial for improving the thermal and electrical performance of the power semiconductor module.

The power electrode of the power semiconductor die may be formed on the main surface of the power semiconductor die.

Advantageously, directly attaching the main surface of the power semiconductor die to the first surface of the die pad achieves the mechanical, thermal and electrical connections between the power semiconductor die and the leadframe simultaneously. The power electrode and the main surface of the power semiconductor die may be a first power electrode and a first main surface of the power semiconductor die, respectively. The power semiconductor die may further comprise a second power electrode and a second main surface opposite to the first main surface. The second power electrode may be formed on the second main surface.

The power semiconductor module may further comprise a conductive clip structure electrically connecting the second power electrode to a further power lead of the leadframe or a power terminal moulded within the housing.

The conductive clip structure is able to carry a high level of current, and has high thermal capability, high short circuit capability and a low inductance. Therefore, as compared to a bone wire connection used in conventional power semiconductor modules, the conductive clip structure achieve higher power cycling capability and higher reliability. Further, the use of the conductive clip structure improves the uniformity of die temperature within the module.

The encapsulant may be configured to encapsulate the conductive clip structure.

The conductive clip structure may comprise a contact portion directly mounted on the second power electrode, and a bridge portion extending between the second power electrode and the further power lead or the power terminal moulded within the housing.

The contact portion and the second power electrode may have an overlapped area.

The overlapped area between the contact portion and the second power electrode is useful for reducing the parasitic inductance of the conductive clip structure.

The bridge portion may be bent at a predetermined angle from the contact portion.

The bending bridge portion is useful when the second power electrode and the further power lead (or the power terminal moulded within the housing) are located at different elevations from of the leadframe.

The conductive clip structure may comprise a copper clip.

The power semiconductor die may comprise a control electrode configured to switch a power current flowing between the first power electrode and the second power electrode.

The housing may comprise a control terminal moulded therein. The control terminal may be electrically connected to the control electrode, and at least a part of the control terminal may be exposed to the exterior of the power semiconductor module.

The control electrode may be electrically connected to the control terminal by a bonding wire.

The power semiconductor die may comprise an insulated gate bipolar transistor, IGBT, and the control electrode may comprise a gate electrode, with the first and second power electrodes being a collector electrode and an emitter electrode of the IGBT, respectively. The control terminal may comprise a gate terminal electrically connected to the gate electrode and an auxiliary emitter terminal electrically connected to the emitter electrode of the IGBT.

Advantageously, the use of the auxiliary emitter terminal is useful for reducing the power and control loop common inductance of the IGBT.

The power semiconductor module may further comprise a power diode. A main surface of the power diode may be directly attached to the first surface of the die pad, and a power electrode of the power diode may be electrically connected to the power lead.

The power diode may be connected in inverse-parallel to the power semiconductor die (e.g., IGBT). In this way, the power diode and the power semiconductor die collectively form a power switch, which may be used as either a high side switch or a low side switch of a half-bridge structure.

The power electrode of the power diode may be formed on the main surface of the power diode. The power electrode and the main surface of the power diode may be a first power electrode and a first main surface of the power diode, respectively. The power diode may comprise a second power electrode and a second main surface opposite to the first main surface, and the second power electrode is formed on the second main surface.

The or a further conductive clip structure may be used to electrically connect the second power electrode of the power diode to the further power lead of the leadframe or the power terminal moulded within the housing.

The housing may comprise a power terminal moulded therein. A part of the power terminal may be exposed to the exterior of the power semiconductor module.

The die pad and the power lead of the leadframe may be a first die pad and a first power lead, respectively. The leadframe may comprise a second die pad and a second power lead. The second die pad may have a third surface facing the power semiconductor die and a fourth surface opposite to the third surface. The fourth surface may be exposed to an exterior of the power semiconductor module. At least a part of the second power lead may also be exposed to the exterior of the power semiconductor module.

The second power lead may extend from the second die pad and thus be electrically connected to the second die pad.

The first and second die pads may be spaced apart from one another. It would be understood that without further connection structures (clip or bonding wires), the first and second die pads are electrically isolated from one another. The second die pad may be coplanar with the first die pad.

The power semiconductor die may be a first power semiconductor die, and the power semiconductor module may further comprise a second power semiconductor die. A main surface of the second power semiconductor die may be directly attached to the third surface of the second die pad, and a power electrode of the second power semiconductor die may be electrically connected to the second power lead.

Optional features described above in relation to the (first) power semiconductor die also apply to the second power semiconductor die.

The first power semiconductor die and the second power semiconductor die may form a half-bridge structure.

To form the half-bridge structure, the power semiconductor module may comprise a first conductive clip structure electrically connecting the second power electrode of the first power semiconductor die to the second power lead or the power terminal moulded within the housing, and a second conductive clip structure electrically connecting the second power electrode of the second power semiconductor die to the first power lead or the power terminal moulded within the housing. It would be understood that the particular arrangement of the first/second conductive clip structure depends upon the intended functions of the power leads/terminal, as well as the layout of power electrodes on the firs/second power semiconductor die.

A thickness of the leadframe may be at least about 1.5 millimetres.

The encapsulant may comprise an epoxy moulding compound.

Advantageously, epoxy moulding compound (EMC) offers good humidity protection, and has a coefficient of thermal expansion that matches with that of copper (which is a common material of the leadframe and the conductive clip structure). Therefore, using EMC as the encapsulant provides a high operational temperature and high reliability.

The housing may be an injection-moulded housing.

Advantageously, the injection-moulded housing has an improved mechanical robustness, and also allows control terminal(s) and power terminal(s) to be easily incorporated within the housing.

The electrically insulating material of the housing may comprise one or more of polybutylene terephthalate resin and polyphenylene sulfide resin.

According to a second aspect of this disclosure, there is provided a power semiconductor assembly, comprising: the power semiconductor module of the first aspect; and a heat sink attached to the second surface of the die pad via a thermal interface material.

The thermal interface material may comprise aluminium nitride. The heat sink may also be attached to the fourth surface of the second die pad.

According to a third aspect of this disclosure there is provided a hybrid electric vehicle or an electric vehicle, comprising the power semiconductor assembly of the second aspect.

According to a fourth aspect of this disclosure there is provided a method of manufacturing a power semiconductor module, comprising:
attaching a main surface of a power semiconductor die to a first surface of a die pad of a leadframe, wherein the die pad comprises a second surface opposite to the first surface, and the leadframe comprises a power lead;
electrically connecting a power electrode of the power semiconductor die to the power lead;
mounting a housing on the leadframe such that the housing surrounds a periphery of the power semiconductor die, wherein the housing comprises an electrically insulating material; and
encapsulating the power semiconductor die and part of the leadframe with an encapsulant, wherein the encapsulant is surrounded by the housing, and the second surface of the die pad and at least a part of the power lead are exposed to an exterior of the power semiconductor module.

The method may further comprise: injection moulding the electrically insulating material to form the housing.

The term “about” or “approximately” used in the present disclosure indicate a degree of variability (e.g., 20%) in the stated numerical values.

Within the present disclosure, the term “electrically connected” describes a permanent low-ohmic connection between electrically connected elements, for example a direct contact between the concerned elements or a low-ohmic connection via metal conductor(s).

It would also be understood that the terms “first”, “second”, “third” and “fourth” are simply used in the present disclosure to label the relevant elements (“surface”, “power lead”, “power electrode”, “die pad” etc.) for the ease of description, and do not imply any limitations to the sequence, locations or total number of the relevant elements.

Where appropriate any of the optional features described above in relation to one of the aspects of the disclosure may be applied to another one of the aspects of the disclosure.

### BRIEF DESCRIPTION OF THE DRAWINGS

In order that the disclosure may be more fully understood, a number of embodiments of the disclosure will now be described, by way of example, with reference to the accompanying drawings, in which:

FIG. 1 schematically illustrates a circuit diagram of a half-bridge structure;

FIG. 2 is a schematic representation of a top plan view of a power semiconductor module according to a first embodiment of the present disclosure;

FIGS. 3a to 3f schematically illustrate an assembly process of the power semiconductor module of FIG. 2;

FIG. 4 is a schematic representation of a cross-sectional view of the power semiconductor module of FIG. 2 when the module is cut along line IV-IV′ in FIG. 3f;

FIG. 5 is a schematic representation of a cross-sectional view of the power semiconductor module of FIG. 2 when the module is cut along line V-V′ in FIG. 3f;

FIG. 6 is a schematic representation of a cross-sectional view of the power semiconductor module of FIG. 2 when the module is used with a heat sink;

FIG. 7 is a schematic representation of a top plan view of a power semiconductor module (with encapsulant being invisible) according to a second embodiment of the present disclosure;

FIG. 8 schematically illustrates processing steps of a method for manufacturing a power semiconductor module according to the present disclosure.

In the figures, like parts are denoted by like reference numerals.

It will be appreciated that the drawings are for illustration purposes only and are not drawn to scale.

### DETAILED DESCRIPTION OF THE PREFERRED EMBODIMENTS

FIG. 1 shows a circuit diagram of a half-bridge structure 100 which is commonly used in power electronic systems (e.g., EV and HEV applications). The half-bridge structure 100 incudes a high-side power switch 120 connected between a DC positive power terminal ‘DC+’ and an output power terminal ‘AC’, and a low-side power switch 140 connected between the output power terminal ‘AC’ and a DC negative power terminal ‘DC−’.

The high-side power switch 120 includes two power transistors T1, T2 in anti-parallel connection with two power diodes D1, D2. The low-side power switch 140 includes two power transistors T3, T4 in anti-parallel connection with two power diodes D3, D4.

In use, the half-bridge structure 100 provides one phase of a power converter. In the example of FIG. 1, the power transistors T1 to T4 are insulated gate bipolar transistors (IGBT). However, it would be appreciated that the power transistors T1 to T4 may be other types of power transistors, e.g., power metal-oxide-semiconductor field-effect transistor (MOSFET), an injection enhanced gate transistor (IEGT), a power bipolar junction transistor (BJT), an integrated gate-commutated thyristor (IGCT), and a gate turn-off thyristor (GTO), etc. The power diodes D1 to D4 may be fast recovery diodes (FRD) or Schottky diodes. Alternatively, the power diodes D1 to D4 may be omitted in favour of a parasitic body diode of the power transistors T1 to T4.

The power transistor T1 has a pair of control terminals G1, E1 for switching on/off a power current flowing between a collector and an emitter (which are power terminals) the power transistor T1. Similarly, the transistors T2 to T4 have control terminals G2&E2, G3&E3, and G4&E4 respectively. The terminals G1 to G4 are gate terminals, while the terminals E1 to E4 are auxiliary emitter terminals.

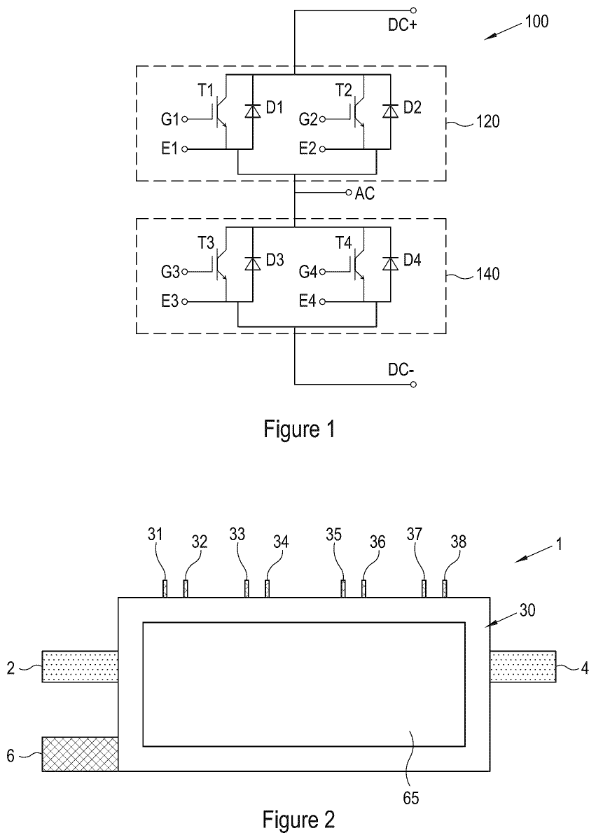

FIGS. 2 to 5 schematically illustrates the structure of a power semiconductor module 1 (hereinafter, “module 1”) that implements the half-bridge structure 100.

FIG. 2 is a top plan view of the module 1. As shown in FIG. 2, the module 1 includes power terminals 2, 4, 6, control terminals 31 to 38, a loop-shaped housing 30 and an encapsulant 65 surrounded by the housing 30. Because the encapsulant 65 is non-transparent, the internal structure of the module 1 is invisible in FIG. 2.

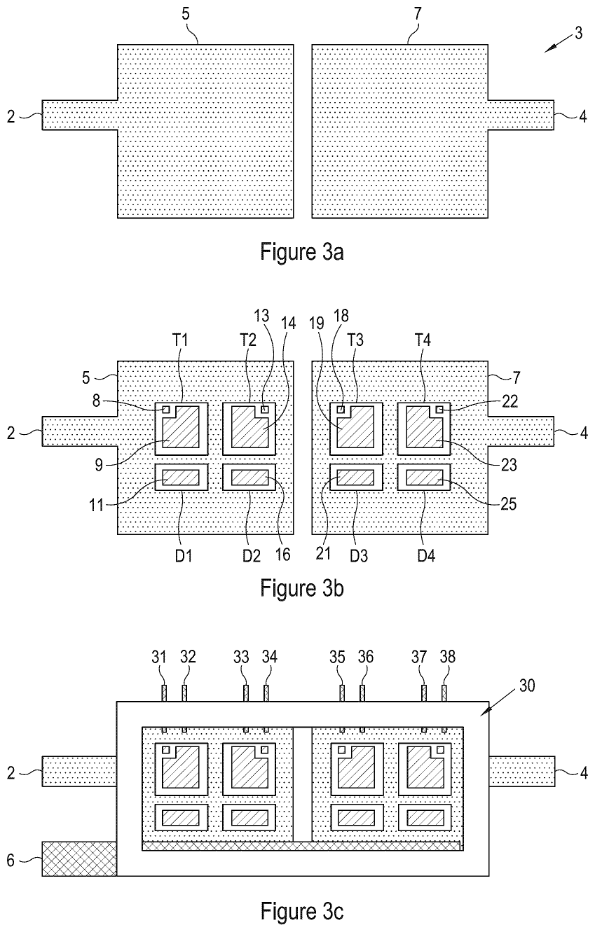

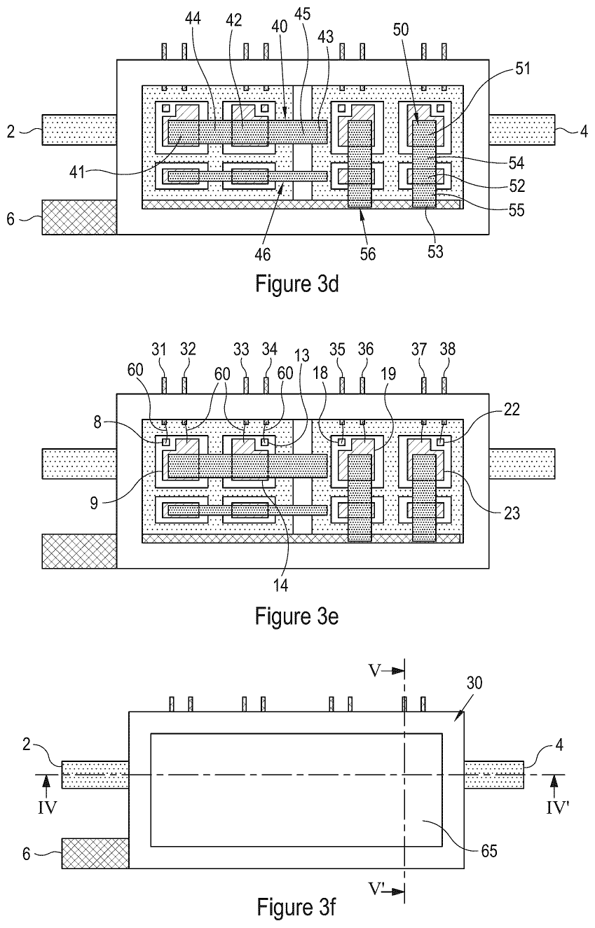

FIGS. 3a to 3f schematically illustrate an assembly process of the module 1. Each of FIGS. 3a to 3f is a top plan view corresponding to FIG. 2.

FIG. 3a shows a leadframe 3 which acts as a base of the module 1. The leadframe 3 has a first die pad 5, a second die pad 7, a first power lead 2 extending from the first die pad 5, and a second power lead 4 extending from the second die pad 7. The die pads 5, 7 are for carrying power semiconductor dies. The power leads 2, 4 are for electrically connecting the semiconductor dies to an external electronic environment of the module 1, in particular, a high power-rating voltage/current.

The first and second die pads 5, 7 are spaced apart from one another. It would be understood that without further electrical connection structures (e.g., clips or bonding wires), the first and second die pads 5, 7 would be electrically isolated from one another. The die pads 5, 7 are generally coplanar with one another, such that their surfaces are located at the same levels.

While it is not shown in FIG. 3a, it would be understood that the leadframe 3 may comprise holding structures (e.g., dam-bar, side rails) to temporarily join the die pads 5, 7 together. The holding structures make the whole leadframe 3 easy to handle as a single-piece item during the manufacturing process of the leadframe 3 and/or the assembly process of the module 1. In the final stage of the manufacturing/assembly process, the holding structures are cut off, thereby separating the die pads 5, 7 to achieve electrical insulation therebetween.

The leadframe 3 may be formed by etching a metal plate of copper (Cu), nickel (Ni), or aluminium (Al) or their alloys. The metal plate may be further coated with silver (Ag) or gold (Au) or the like, for example. The thickness of the leadframe 3 may be at least approximately 1.5 mm, and preferably more than approximately 2 mm, when the leadframe 3 is primarily made of copper. The thickness is defined along a third direction perpendicular to a surface of the die pads 5, 7 shown in FIG. 3a. In general, a greater thickness allows the leadframe 3 to have higher electrical and thermal conductance, which is beneficial for the performance of the module 1 as described below in more detail.

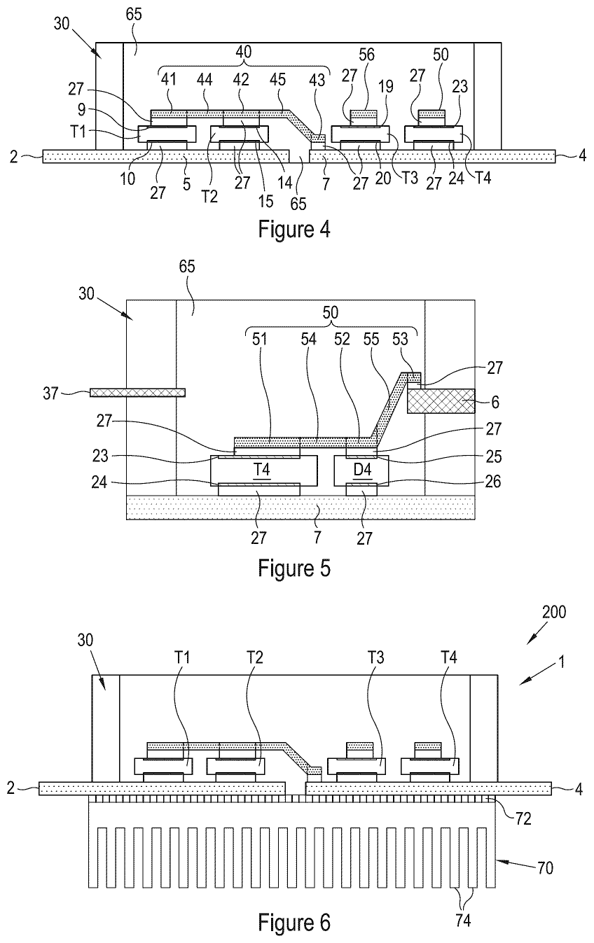

FIG. 3b shows that IGBT dies T1, T2 and power diodes D1, D2 are directly attached to a top surface of the first die pad 5, and that IGBT dies T3, T4 and power diodes D3, D4 are directly attached to a top surface of the second die pad 7. It would be understood that in FIGS. 3a to 3f, the “top surface” of an element refers to the visible surface of the relevant element, and the “bottom surface” is at an opposite side of the element and hence remains invisible. The power semiconductor dies T1-T4, D1-D4 may be pre-packaged bare dies or packaged chips. The attachment may be done by soldering or sintering. Therefore, an interface layer 27 (e.g., solder or sintering paste, as shown in FIGS. 4 and 5) may be used between the bottom surface of each IGBT die/power diode and the top surface of a corresponding die pad 5, 7, so as to securely bond the IGBT dies and the power diodes to the die pads. There is no further structure/component between the die pads 5 and the IGBT dies T1-T4 (or the diodes D1-D4).

The IGBT die T1 includes a gate electrode 8 and an emitter electrode 9 at its top surface, and a collector electrode 10 at its bottom surface (visible in FIG. 4). The gate electrode 8 is a control electrode, and the emitter and collector electrodes are power electrodes. In particular, a voltage difference between the gate electrode 8 and the emitter electrode 9 determines the on/off status of a power current path between the emitter electrode 9 and the collector electrode 10. Similarly, the IGBT die T2 includes a gate electrode 13 and an emitter electrode 14 at its top surface, and a collector electrode 15 at its bottom surface (visible in FIG. 4). The IGBT die T3 includes a gate electrode 18 and an emitter electrode 19 at its top surface, and a collector electrode 20 at its bottom surface (visible FIG. 4). The IGBT die T4 includes a gate electrode 22 and an emitter electrode 23 at its top surface, and a collector electrode 24 at its bottom surface (visible in FIG. 4).

The power diode D1 includes an anode 11 at its top surface and a cathode at its bottom surface. Similarly, the diodes D2 to D4 have anodes 16, 21 and 25 at their top surfaces, and cathodes at their bottom surfaces. The anodes and cathodes are power electrodes of the diodes D1 to D4.

In the example of FIG. 2, because the cathodes of the diodes D1, D2 and the collectors of the IGBT dies T1, T2 are all directly attached (hence electrically connected) to the die pad 5, the first die pad 5 and the first power lead 2 function as the DC positive power terminal ‘DC+’. Similarly, the second die pad 7 and the second power lead 4 function as the output power terminal ‘AC’ of the half-bridge structure 100.

FIG. 3c shows that a housing 30 is mounted on the leadframe 3. The housing 30 is loop shaped and surrounds a periphery of the IGBT dies T1-T4 and the power didoes D1-D4. It would be appreciated that the housing 30 may have any suitable cross-sectional shape which is not limited to the rectangular shape as shown in FIG. 3c. For example, the housing 30 may assume a loop shape that is oval, annular, square, polygonal or non-geometrical, etc., as long as it forms a closed loop that is without a gap, when viewed in the top plan view of the module 1.

The housing 30 is primarily made of an electrically insulating material, but has control terminals 31 to 38 and a power terminal 6 moulded therein. The control terminals 31 to 38 and the power terminal 6 are made of an electrically conductive material, and lie above the top surfaces of the die pads 5, 7 (as shown in FIG. 5). Therefore, without further electrical connection structures (such as clips or bonding wires), the first and second die pads 5, 7 would be electrically isolated from the control terminals 31 to 38 and the power terminal 6. The control terminals 31 to 38 and the power terminal 6 are further electrically isolated from one another due to the use of the electrically insulating material in the housing 30.

The power terminal 6 functions as the DC negative power terminal ‘DC−’ of the half-bridge structure 100.

The electrically insulating material may be an injection-moulded insulating engineering plastic, such as polybutylene terephthalate (PBT) resin or polyphenylene sulfide (PPS) resin. The PBT resin is able to support an operating temperature of up to 175° C. while the PPS resin typically supports an operating temperature of up to 125° C. Therefore, the electrically insulating material of the housing 30 may be suitably selected based upon the expected operating temperature of the module 1.

The housing 30 may be an injection-moulded housing. Using injection moulding to make the housing 30 allows the housing 30 to have an improved mechanical robustness as compared to other moulding methods, and also allows control terminals 31-38 and power terminal 6 to be easily incorporated within the housing during the manufacturing processes. It would be understood that the housing 30, the control terminals 31 to 38 and the power terminal 6 are handled as a single-piece item. Therefore, the use of the housing 30 reduces the number of processing steps for manufacturing the module 1.

The housing 30 may be mounted on the leadframe 3 by using any suitable fastening means (e.g., adhesives, screws, bolts and nuts, etc.). The housing 30 may also be referred to as a frame or a plastic frame.

FIG. 3d shows that conductive clip structures (hereinafter, “clips”) 40, 46, 50, 56 are applied to form the electrical interconnections between the IGBT dies T1-T4, the power diodes D1-D4 and the power terminals 2, 4, 6.

The clip 40 electrically connects the emitter electrode 9 of IGBT die T1 and the emitter electrode 14 of IGBT die T2 to the second die pad 7 (which is electrically connected to the second power lead 4, i.e., the output power terminal ‘AC’). In particular, the clip 40 has a contact portion 41 electrically connected to the emitter electrode 9, a contact portion 42 electrically connected to the emitter electrode 14, and a contact portion 43 electrically connected to the second die pad 7. The clip 40 further has a bridge portion 44 extending between the contact portions 41, 42, and a bridge portion 45 extending between the contact portions 42, 43.

A cross-sectional shape of the clip 40 is shown more clearly in FIG. 4. FIG. 4 shows that the bridge portion 45 is bent at an angle from the contact portion 42 or 43, because the emitter electrode 14 of the IGBT die T2 and the second die pad 7 are located at different elevations from the bottom surface of the module 1. The contact portions 41, 42, 43 are attached to the emitter electrodes 9, 14 or the die pad 7 using the interface layer 27 (e.g., solder or sintering paste). The interface layer 27 achieves the mechanical, electrical and thermal connections between the clip 40 and the corresponding electrodes/die pad.

Similar to the clip 40, the clip 46 electrically connects the anode 11 of diode D1 and the anode 16 of diode D2 to the second die pad 7 (which is electrically connected to the second power lead 4, i.e., the output power terminal ‘AC’).

The contact portion 41 and the emitter electrode 9 have a substantial overlapping area, which may be more than about 50% of the total area of the emitter electrode 9. The large overlapping area is useful for reducing the parasitic inductance of the clip 40. Similar features and advantages apply to other contact portions of the clips described herein.

The clip 50 electrically connects the emitter electrode 23 of IGBT die T4 and the anode 25 of the diode D4 to the power terminal 6 (i.e., the DC negative power terminal ‘DC−’). In particular, the clip 50 has a contact portion 51 electrically connected to the emitter electrode 23, a contact portion 52 electrically connected to the anode 25, and a contact portion 53 electrically connected to the power terminal 6. The clip 50 further has a bridge portion 54 extending between the contact portions 51, 52, and a bridge portion 55 extending between the contact portions 52, 53.

A cross-sectional shape of the clip 50 is shown more clearly in FIG. 5. FIG. 5 shows that the bridge portion 55 is bent at an angle from the contact portion 52 or 53, because the anode 25 of the diode D4 and the power terminal 6 are located at different elevations from the bottom surface of the module 1. It would be understood that the angles of the bridge portions 44, 45, 54, 55 may be suitable adjusted depending upon the elevations of the contact portions. Alternatively, one or more of the bridge portions 44, 45, 54, 55 may have a stepped structure or a zigzag structure. The contact portions 51, 52, 53 are attached to the power electrodes 24, 25 or the power terminal 6 using the interface layer 27 (e.g., solder or sintering paste). The interface layer 27 achieves the mechanical, electrical and thermal connections between the clip 50 and the corresponding power electrodes/terminal.

Similar to the clip 50, the clip 56 electrically connects the emitter electrode 19 of IGBT die T3 and the anode 21 of the diode D3 to the power terminal 6 (i.e., the DC negative power terminal ‘DC−’).

Clips are able to carry higher levels of current, and have higher thermal capability, higher short circuit capability and lower inductances, than bonding wire connections that are commonly used in conventional power modules. Therefore, the use of the clips allows the module 1 to have a high power cycling capability and thus a high reliability. Further, the clips are also useful for distributing heat within the module 1, thereby improving the uniformity of die temperatures within the module 1.

By way of an example, the clips 40, 46, 50, 56 are copper clips. However, it would be understood that the clips may be made of any suitable conductive materials such as Cu, Al, noble metal, and alloys thereof. Further, bottom surfaces of the clips 40, 46, 50, 56 may be wholly or partially plated with the interface layer 27 before the clips 40, 46, 50, 56 are bonded to the power electrodes or the power terminals.

FIG. 3e shows that bonding wires 60 are applied to form the electrical connections between the control terminals 31-38 and the electrodes of the IGBT dies T1-T4. In particular, the control terminal 31 is connected to the gate electrode 8 of the IGBT die T1 via a bonding wire 60, and the control terminal 32 is connected to the emitter electrode 9 of the IGBT die T1 via another bonding wire 60. Therefore, the control terminals 31, 32 function as the G1, E1 terminals of FIG. 1. Similarly, the control terminals 33 to 38 function as the terminals E2, G2, G3, E3, E4, G4 of FIG. 1, respectively. The use of the auxiliary emitter terminals 32, 33, 36, 37 reduces the power and control loop common inductance of the IGBT dies T1-T2, and of the IGBT dies T3-T4. Reducing the power and control loop common inductance is useful for improving the simultaneous switching of the IGBT dies T1-T2 (or the IGBT dies T3-T4), thereby improving the current sharing between the IGBT dies T1-T2 (or the IGBT dies T3-T4) and thus the reliability of the module 1 as a whole.

FIG. 5 shows the cross-sectional view of the control terminal 37. In this example, the control terminal 37 is above the emitter electrode 23 of the IGBT die T4. However, it would be understood that the height of the control terminals 31 to 38 can be suitably varied.

FIG. 3f shows that an encapsulant 65 is applied to seal the IGBT dies T1-T4, the diodes D1-D4, the clips 40, 46, 50, 56 and the bonding wires 60, thereby protecting those components from humidity and corrosive gases. With reference to FIGS. 4 and 5, it can be seen that the encapsulant 65 also fills the gap between the die pads 5, 7, and the space surrounded by the top surfaces of the die pads 5, 7 and the inner surface of the housing 30.

Silicone gel is conventionally used as the encapsulant 65 for high power-rating power modules such as the module 1. However, in the present disclosure, epoxy moulding compound (EMC) is preferably used as the encapsulant 65. As compared to silicone gel, EMC has a coefficient of thermal expansion (CTE) that matches with that of copper (which is a common material of the leadframe 3 and the clips 40, 46, 50, 56). Therefore, using EMC as the encapsulant 65 allows a higher operating temperature and provides a higher thermal cycling reliability than using silicone gel. The encapsulant 65 made of EMC is also vibration-resistant, and therefore offers better protection to the dies and connection structures within the module 1. EMC is generally potted and cured at a high temperature.

With reference to FIGS. 4 and 5, it can be seen that the side boundary of the module 1 is defined by the housing 30, and the encapsulant 65 is confined by the housing 30. This is in contrast to low power-rating power modules, in which the side boundaries thereof are defined by singulation process (e.g., sawing or punching the encapsulant). FIG. 6 schematically illustrates a power semiconductor assembly 200 including the module 1 and a heat sink 70. The heat sink 70 is attached to the bottom surface of the leadframe 3 using a thermal interface material 72. By way of an example, the thermal interface material 72 is aluminium nitride, which has good thermal conductance but is electrically insulating. Therefore, the power leads 2, 4 would not be shorted together by the heat sink 70. The heat sink 70 includes a number of fins 74. In use, heat generated by the IGBT dies T1-T4 and the diodes D1-D4 dissipates into exterior through the leadframe 3, the thermal interface material 72 and the heat sink 72.

With further reference to FIGS. 4 and 5, it can be seen that the encapsulant 65 does not cover the bottom surface of the leadframe 3. Therefore, the bottom surfaces of the die pads 5, 7 and of the power leads 2, 4 are exposed to an exterior of the module 1.

As described above, the IGBT dies T1-T4 and the diodes D1-D4 are directly attached to the top surface of the leadframe 3. Since the bottom surface of the leadframe 3 is exposed to the exterior of the module 1, the junction-to-case thermal resistance of the module 1 is at a very low level. The junction-to-case thermal resistance is the thermal resistance from the bottom surfaces of the dies to the bottom surface of the casing of the module 1. In this example, the casing of the module 1 is the leadframe 3. A low junction-to-case thermal resistance means that, during operation of the module 1, the junction temperature between the dies and the leadframe 3 would not increase significantly, because the generated heat would efficiently dissipate to exterior through the heat sink 70. Therefore, the structure of the module 1 is beneficial for improving the power cycling capability and the thermal reliability of the module 1.

As described above with reference to FIGS. 3a to 3f, the module 1 uses the leadframe 3 as a die carrier to physically support the IGBT dies T1-T4 and the diodes D1-D4. Therefore, there is no need to provide a further substrate (e.g., a DBC substrate) or a thick baseplate within the module 1. This means that the thickness of the module 1 is much thinner than conventional power modules which use substrate(s) and/or baseplate(s) to support dies. Accordingly, the module is more compact and have a lower volume (hence a higher power density) than conventional power modules.

In conventional power modules, common points of failures include bonding wires used in power current flow paths, silicone gel used to seal dies, and interfaces between the dies and substrate(s) due to high junction-to-case thermal resistance. The module 1 has eliminated those points of common failures, by using the clips 40, 46, 50, 56 in the power current flow path, the injection moulded housing 30 and the EMC-based encapsulant 65, and also by not using any substrate within the module. Therefore, the module 1 has an improved reliability as compared to conventional power modules.

As described above, the first power lead 2 is integrally formed with the first die pad 5. Therefore, the first power lead 2 and the first die pad 5 share substantially the same voltage potential in use and can be regarded collectively as a large-area power terminal of the module 1. Similarly, the second power lead 4 and the second die pad 7 may be regarded as another large-area power terminal of the module 1. The large-area power terminals of the module 1 provide a high current carrying capability, a high thermal dissipation rate and a low inductance, which are beneficial for improving the thermal and electrical performance of the module 1. However, it would be understood that one or more of the power leads 2, 4 may be spaced apart from the die pads 5, 7. That is, the power leads 2, 4 may be disposed in a peripheral region of the die pads 5, 7 with a gap. In that case, further electrical connections (e.g., clips) may be used to connect the power leads 2, 4 to the power dies or the die pads.

In the module 1, the IGBT dies T1-T4 and the diodes D1-D4 are vertical power semiconductor dies, meaning that power current flows vertically through them. A vertical power die typically have a pair of power electrodes arranged at the opposite main surfaces (as compared to side surfaces with much less surface areas) of the die. By using vertical power dies, directly attaching main surfaces of the power dies to the leadframe 3 completes the mechanical, thermal and electrical connections between the power dies and the leadframe 3 simultaneously. However, it would be understood that lateral power dies may be used instead within the module 1. For a lateral power die, its power electrodes are typically arranged on its top surface. Therefore, the electrical connections for the lateral power die may be more complicated than the case of using vertical dies.

In the example described above, the entire leadframe 3 is located within a single plane. It would be understood that the leadframe 3 may be modified such that, for example, one or more of the power leads 2, 4 form an angle with respect to the die pads 5, 7. Further, the module 1 may be modified such that only part of the bottom surfaces of the die pads 5, 7 are exposed to an exterior of the module 1.

It would further be appreciated that the module 1 may comprise different types/numbers of power semiconductor dies that are suitably interconnected to form a different circuit structure (e.g., multiple half-bridge structures, an AC-to-DC power converter, a buck or boost DC-to-DC power converter etc.). In particular, this may be achieved by modifying the number of power terminal(s) and control terminal(s) moulded within the housing 30, and by modifying the connections provided by the clips as well as the number of clips used within the module 1.

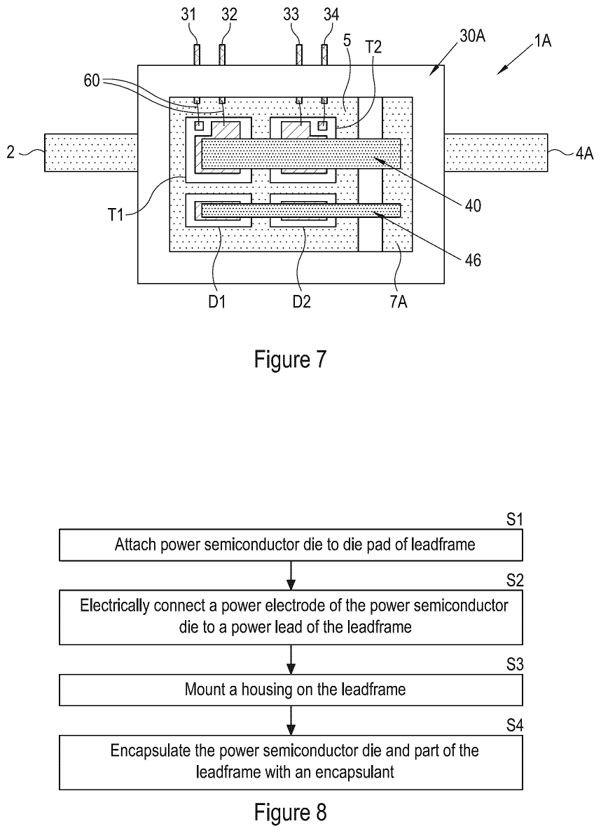

FIG. 7 schematically illustrates a power semiconductor module 1A according to a second embodiment of the present disclosure. Elements of the module 1A that are identical to those of the module 1 are identified using the same labels. Elements of the module 1A that correspond to, but are different from those of the module 1 are labelled using the same numerals but with a letter ‘A’ for differentiation. The features and advantages described above with reference to the first embodiment are generally applicable to the second embodiment.

The module 1A differs from the module 1 in that it implements a single power switch, rather than a half-bridge structure. The single power switch implemented by the module 1A may be used as either a high-side power switch or a low-side power switch of a half-bridge structure. In the example of FIG. 7, the encapsulant of the module 1A is invisible, thereby revealing the internal structure of the module 1A. It can be seen that the leadframe of the module 1A includes a single die pad 5 on which IGBT dies T1-T2 and diodes D1-D2 are directly mounted. The leadframe of the module 1A further includes a first power lead 2 extending from the single die pad 5 and a second power lead 4A spaced apart from the single die pad 5. Clips 40, 46 electrically connect emitter electrodes of the IGBT dies T1-T2 and anodes of the diodes D1-D2 to the second power lead 4A. The housing 30A of the module 1A has control terminals 30-34 moulded therein. The control terminals 30-34, upon application of control signals, control a power current path between the first power lead 2 and the second power lead 4A. There is no further power terminal moulded within the housing 30A. The housing 30A is otherwise identical to the housing 30.

In each of the module 1 and the module 1A, two power transistors (e.g., IGBT dies T1&T2, or T3&T4) are connected in parallel to form a power switch, thereby increasing the current rating of the power switch. It would be appreciated that the number of power transistors included within each switch can be suitably varied depending upon the required rating of the switch.

FIG. 8 schematically illustrates processing steps of a method for manufacturing a power semiconductor module (e.g., either of the modules 1, 1A).

At step S1, a main surface (e.g., the bottom surface) of a power semiconductor die (e.g., any of the IGBT dies T1-T4, the diodes D1-D4) is attached to a first surface (e.g., the top surface) of a die pad (e.g., the die pad 5 or 7) of a leadframe (e.g., the leadframe 3). The die pad comprises a second surface (e.g., the bottom surface) opposite to the first surface, and the leadframe comprises a power lead (e.g., the power lead 2 or 4).

At step S2, a power electrode (e.g., any of the emitter/collector electrode or the anode/cathode) of the power semiconductor die is electrically connected to the power lead.

At step S3, a housing (e.g., the housing 30) is mounted on the leadframe such that the housing surrounds a periphery of the power semiconductor die. The housing comprises an electrically insulating material (e.g., PBT resin or PPS resin).

At step S4, the power semiconductor die and part of the leadframe are encapsulated with an encapsulant (e.g., the encapsulant 65). The encapsulant is surrounded by the housing, and the second surface of the die pad and at least a part of the power lead are exposed to an exterior of the power semiconductor module.

The method may further include an optional processing step of injection moulding the electrically insulating material to form the housing.

It would be appreciated that the steps may be performed in a temporal order that is different from the order of description. For example, steps S1 and S2 may be performed simultaneously if the power electrode is formed on the main surface of the power semiconductor die.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘top’, ‘bottom’, ‘lateral’, ‘vertical’, etc. are made with reference to conceptual illustrations of a semiconductor device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A power semiconductor module, comprising:
a power semiconductor die;
a leadframe comprising a die pad and a power lead, wherein the die pad has a first surface facing the power semiconductor die and a second surface opposite to the first surface, wherein a main surface of the power semiconductor die is directly attached to the first surface of the die pad, and a power electrode of the power semiconductor die is electrically connected to the power lead;
a housing mounted on the leadframe and surrounding a periphery of the power semiconductor die, wherein the housing comprises an electrically insulating material; and
an encapsulant surrounded by the housing and encapsulating the power semiconductor die and part of the leadframe, wherein the second surface of the die pad is exposed to an exterior of the power semiconductor module, and wherein at least a part of the power lead is also exposed to the exterior of the power semiconductor module.

2. The power semiconductor module of claim 1, wherein the power lead extends from the die pad and is electrically connected to the die pad.

3. The power semiconductor module of claim 1, wherein the power electrode of the power semiconductor die is formed on the main surface of the power semiconductor die.

4. The power semiconductor module of claim 1, wherein the power electrode and the main surface of the power semiconductor die are a first power electrode and a first main surface of the power semiconductor die, respectively, and
wherein the power semiconductor die further comprises a second power electrode and a second main surface opposite to the first main surface, and the second power electrode is formed on the second main surface.

5. The power semiconductor module of claim 4, further comprising a conductive clip structure electrically connecting the second power electrode to a further power lead of the leadframe or a power terminal moulded within the housing.

6. The power semiconductor module of claim 5, wherein the conductive clip structure comprises a contact portion directly mounted on the second power electrode, and a bridge portion extending between the second power electrode and the further power lead or the power terminal moulded within the housing.

7-10. (canceled)

11. The power semiconductor module of claim 4, wherein:
the power semiconductor die comprises a control electrode configured to switch a power current flowing between the first power electrode and the second power electrode;
the housing comprises a control terminal moulded therein, and wherein the control terminal is electrically connected to the control electrode, ; and
at least a part of the control terminal is exposed to the exterior of the power semiconductor module.

12. The power semiconductor module of claim 11, wherein the control electrode is electrically connected to the control terminal by a bonding wire.

13. The power semiconductor module of claim 4, wherein:
the power semiconductor die comprises a control electrode configured to switch a power current flowing between the first power electrode and the second power electrode;
the power semiconductor die comprises an insulated gate bipolar transistor, IGBT, and the control electrode comprises a gate electrode, with the first and second power electrodes being a collector electrode and an emitter electrode of the IGBT, respectively; and
the control terminal comprises a gate terminal electrically connected to the gate electrode and an auxiliary emitter terminal electrically connected to the emitter electrode of the IGBT.

14. The power semiconductor module of claim 1, further comprising a power diode, wherein a main surface of the power diode is directly attached to the first surface of the die pad, and a power electrode of the power diode is electrically connected to the power lead.

15. The power semiconductor module of claim 1, wherein the housing comprises a power terminal moulded therein, and a part of the power terminal is exposed to the exterior of the power semiconductor module.

16. The power semiconductor module of claim 1, wherein:
the die pad and the power lead of the leadframe is a first die pad and a first power lead, respectively, and the leadframe comprises a second die pad and a second power lead;
the second die pad has a third surface facing the power semiconductor die and a fourth surface opposite to the third surface;
wherein the fourth surface is exposed to an exterior of the power semiconductor module, and wherein at least a part of the second power lead is also exposed to the exterior of the power semiconductor module.

17. The power semiconductor module of claim 16, wherein the power semiconductor die is a first power semiconductor die, and the power semiconductor module further comprises a second power semiconductor die; and
wherein a main surface of the second power semiconductor die is directly attached to the third surface of the second die pad, and a power electrode of the second power semiconductor die is electrically connected to the second power lead.

18. The power semiconductor module of claim 17, wherein the first power semiconductor die and the second power semiconductor die form a half-bridge structure.

19. The power semiconductor module of claim 1, wherein a thickness of the leadframe is at least about 1.5 millimetres.

20. The power semiconductor module of claim 1, wherein the encapsulant comprises an epoxy moulding compound.

21. The power semiconductor module of claim 1, wherein the housing is an injection-moulded housing; and/or
wherein the electrically insulating material of the housing comprises one or more of polybutylene terephthalate resin and polyphenylene sulfide resin.

22. (canceled)

23. A power semiconductor assembly, comprising:
the power semiconductor module of claim 1; and
a heat sink attached to the second surface of the die pad via a thermal interface material.

24. A hybrid electric vehicle or an electric vehicle, comprising the power semiconductor assembly of claim 23.

25. A method of manufacturing a power semiconductor module, comprising:
attaching a main surface of a power semiconductor die to a first surface of a die pad of a leadframe, wherein the die pad comprises a second surface opposite to the first surface, and the leadframe comprises a power lead;
electrically connecting a power electrode of the power semiconductor die to the power lead;
mounting a housing on the leadframe such that the housing surrounds a periphery of the power semiconductor die, wherein the housing comprises an electrically insulating material; and
encapsulating the power semiconductor die and part of the leadframe with an encapsulant, wherein the encapsulant is surrounded by the housing, and the second surface of the die pad and at least a part of the power lead are exposed to an exterior of the power semiconductor module.

26. (canceled)
